(19) United States
(12) Patent Application Publication
(10) Pub. No.: US 2009/0316342 A1
(43) Pub. Date: Dec. 24, 2009

(54) ACCESSORY HOLDING MECHANISM USED IN PORTABLE ELECTRONIC DEVICES

(75) Inventors: HAN-YU LI, Tu-Cheng (TW); HUNG-CHUAN WEN, Tu-Cheng (TW)

Correspondence Address: PCE INDUSTRY, INC.;ATT. Steven Reiss, 288 SOUTH MAYO AVENUE, CITY OF INDUSTRY, CA, 91789, US

(73) Assignee: Chi Mei Communication Systems, Inc., Tu-Cheng City (TW)

(21) Appl. No.: 12/470,621

(22) Filed: May 22, 2009

(30) Foreign Application Priority Data
Jun. 23, 2008 (CN) 200810302276.X

(51) Int. Cl. H05K 7/00

(52) U.S. Cl. 361/679.01

(57) ABSTRACT

An accessory holding mechanism used in a portable electronic device for holding an accessory therein includes a housing, a sliding member, a positioning member and an elastic member. The sliding member is slidably assembled on the housing and receiving the accessory therein. The positioning member is movably mounted on the housing. The elastic member is mounted between the housing and the sliding member. The positioning member engages with the sliding member and the accessory to hold the accessory and the elastic member is elongated when the accessory is pushed into the sliding member, and the elastic member rebounds to drive the positioning member to release the accessory and drive the accessory to exit from the accessory holding mechanism through the sliding member after the held accessory is further pushed into the sliding member.

### BACKGROUND

1. Technical Field

The present invention relates to accessory holding mechanisms, and particularly to an accessory holding mechanism used in portable electronic devices and capable of driving an accessory held therein to exit.

2. Description of Related Art

Portable electronic devices, such as mobile phones, digital cameras or personal digital assistants (PDA), often need additional accessories assembled thereto to enhance their capabilities. For example, batteries are widely used in the portable electronic devices to supply electric power, and memory cards are often used in the portable electronic devices to increase the storage capacity thereof. In assembly, an accessory is generally held in a portable electronic device by a holding mechanism, and is electronically connected to inner circuits of the portable electronic device through the holding mechanism.

When an accessory such as a battery or a memory card is held by a holding mechanism to be used in a portable electronic device, it is usually completely received in the portable electronic device. Thus, it can be difficult to access the accessory directly for removal from the portable electronic device.

Therefore, there is room for improvement within the art.

### BRIEF DESCRIPTION OF THE DRAWINGS

Many aspects of the present accessory holding mechanism can be better understood with reference to the following drawings. The components in the various drawings are not necessarily drawn to scale, the emphasis instead being placed upon clearly illustrating the principles of the present accessory holding mechanism. Moreover, in the drawings, like reference numerals designate corresponding parts throughout the figures.

FIG. 1 is a schematic view of an accessory holding mechanism, according to an exemplary embodiment.

FIG. 2 is an exploded view of the accessory holding mechanism shown in FIG 1.

FIG. 3 is similar to FIG. 2, but shown in another view angle.

FIG. 4 is an assembled view of a portion of the accessory holding mechanism shown in FIG. 1, wherein the accessory holding mechanism is in an accessory ejecting mode.

FIG. 5 is a schematic view of the accessory holding mechanism shown in FIG. 4, when assembling an accessory thereto.

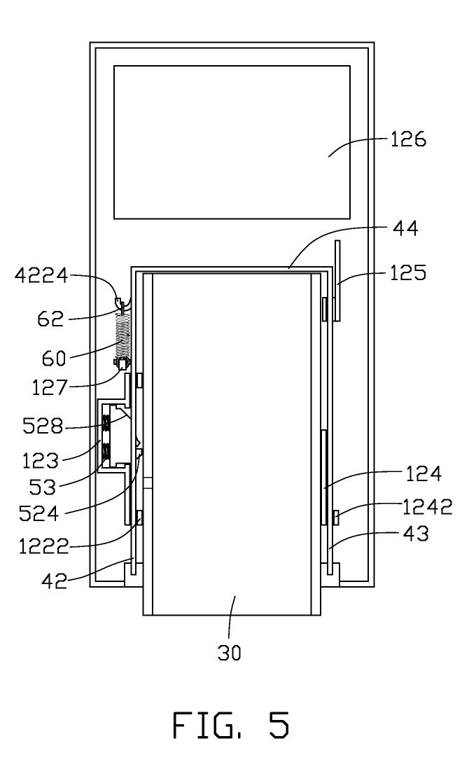

FIG. 6 is a schematic view of the accessory holding mechanism shown in FIG. 1 holding an accessory therein.

FIG. 7 is an assembled view of the accessory holding mechanism shown in FIG. 1, wherein the accessory holding mechanism is in an accessory holding mode.

FIG. 8 is a schematic view of the accessory holding mechanism shown in FIG. 7, when ejecting the accessory therefrom.

### DETAILED DESCRIPTION

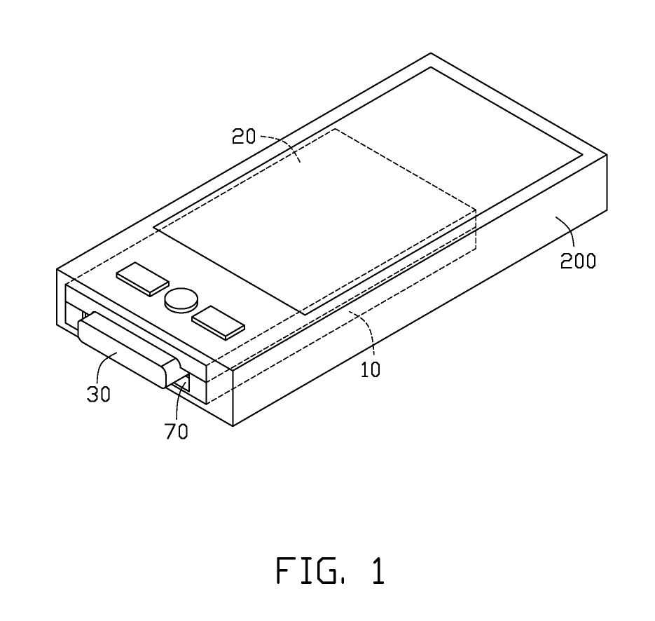

FIGS. 1-3 schematically show an accessory holding mechanism 100 according to an exemplary embodiment, used for holding external accessories in a portable electronic device 200 such as a mobile phone, a digital camera or a personal digital assistant (PDA). An accessory 30, such as a battery or a memory card, can be held by the accessory holding mechanism 30 while received in the portable electronic device 200 and electronically connected thereto, and can also be driven to exit from the portable electronic device 200 by the accessory holding mechanism 100.

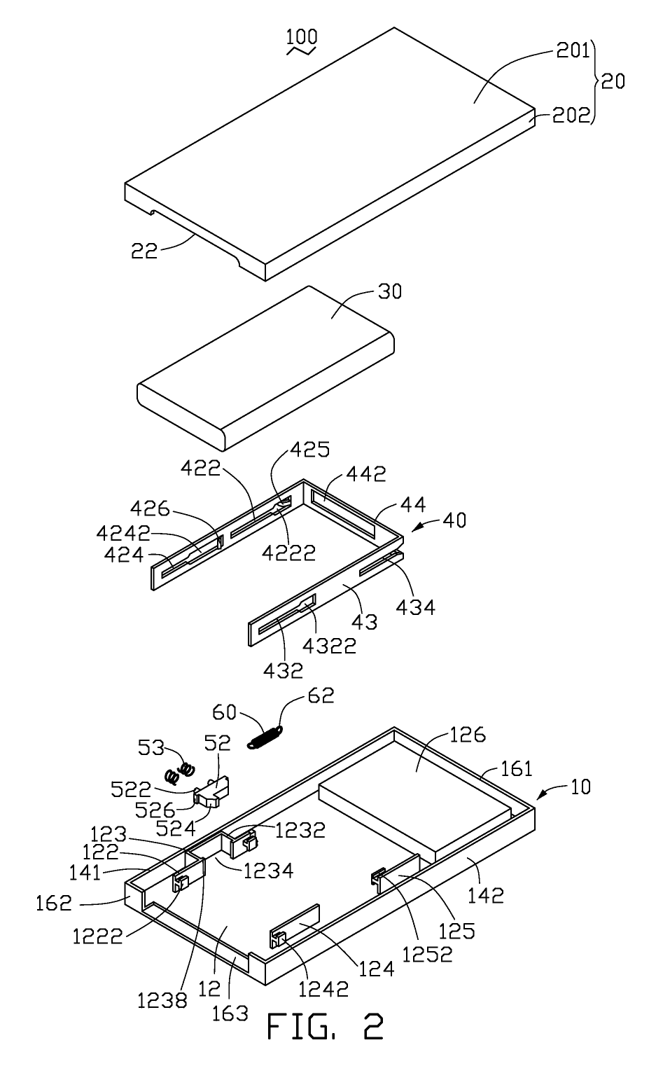

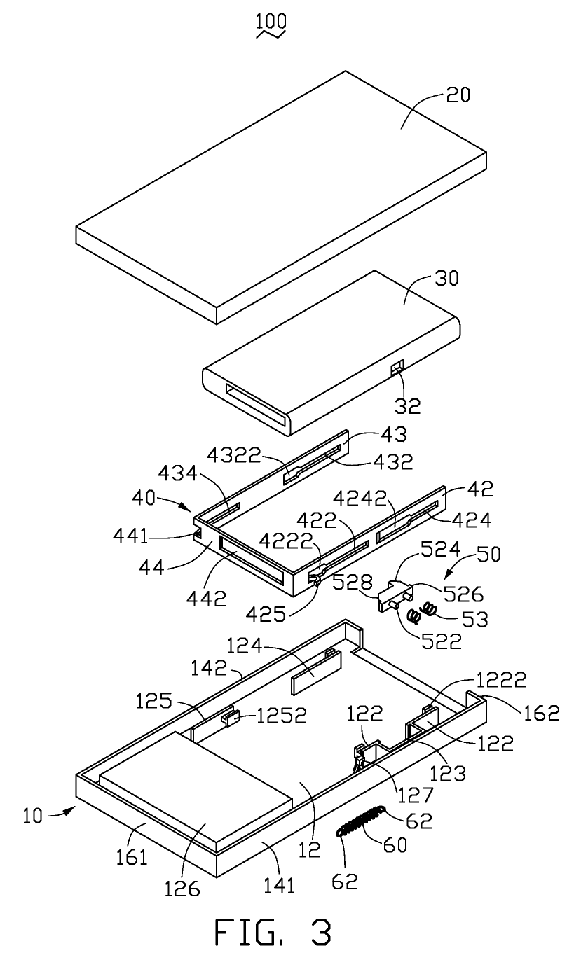

Referring to FIG. 2 and FIG. 3, the accessory holding mechanism 100 includes a housing 10, a cover 20, a sliding member 40, a positioning member 50 and an elastic member 60.

The housing 10 includes a base board 12, two parallel side walls 141, 142 perpendicularly connected to two opposite sides of the base board 12 and two parallel end walls 161, 162 perpendicularly connected to other two opposite sides of the base board 12. The end wall 162 defines an opening 163 in a middle portion thereof to enable inserting the accessory 30 into the accessory holding mechanism 100. Two first guiding walls 122, a connecting wall 123, a second guiding wall 124, a third guiding wall 125, an electronic connector 126 and a connecting hook 127 are formed on the base board 12.

The two first guiding walls 122 are sheets perpendicularly connected to the base board 12 and positioned adjacent to the side wall 141. The two first guiding walls 122 are positioned in a same plane parallel the two side walls 141, 142. Each first guiding wall 122 has a first guiding component 1222 formed thereon and extending towards the side wall 142. Each first guiding component 1222 is a protrusion perpendicularly protruding from the guiding wall 122 and having a T-shaped cross section. The connecting wall 123 is a C-shaped frame perpendicularly connected to the base board 12. The connecting wall 123 is positioned between the two first guiding walls 122 and the side wall 141. The connecting wall 123 includes a planar middle wall parallel attached to the side wall 141 and two extending walls perpendicularly connected to two ends of the middle wall, respectively, and defines a receiving space 1234 surrounded by the connecting wall 123. The two first guiding walls 122 are respectively perpendicularly connected to outer sides of the ends of the two extending walls, and the ends of the two extending walls bend towards each other to form two limiting sides 1238 partially close the receiving space 1234.

The second guiding wall 124 and the third guiding wall 125 are also sheets perpendicularly connected to the base board 12 and positioned adjacent and parallel to the side wall 142. A distance between the second guiding wall 124 and the side wall 142 is longer than a distance between the third guiding wall 125 and the side wall 142. The second guiding wall 124 is positioned opposite to a first guiding wall 122. The second guiding wall 124 and its opposite first guiding wall 122 are both positioned proximate to the end wall 162. A distance between the second guiding wall 124 and the third guiding wall 125 is longer than a distance between the two first guiding walls 122. The second guiding wall 124 includes a second guiding component 1242 formed thereon and the third guiding wall 125 includes a third guiding component 1252 thereon. The shapes of the second guiding component 1242 and the third guiding component 1252 are similar to the first guiding components 1222. The second guiding component 1242 perpendicularly protrudes from the second guiding wall 124 and extends towards the side wall 142. The third guiding component 1252 perpendicularly protrudes from the third guiding wall 125 and extends towards the side wall 141. Thus, the second guiding component 1242 is positioned between the second guiding wall 124 and the side wall 142, and the third guiding wall 125 is positioned between the side wall 142 and the third guiding component 1252.

The electronic connector 126 is formed on the base board 12 and positioned proximate to the end wall 161. When the accessory 30 is received in the accessory holding mechanism 100, it can be electronically connected to circuits (not shown) of the portable electronic device 200 by the electronic connector 126. The connecting hook 127 is formed on the base board 12 and positioned between the electronic connector 126 and the connecting wall 123, advantageously, positioned adjacent to the connecting wall 123 and away from the electronic connector 126.

The sliding member 40 is a U-shaped frame, which includes two parallel side boards 42, 43 and an end board 44. The side boards 42, 43 are bar-shaped boards perpendicularly connected to a same side of the end board 44. The side board 42 defines a first sliding groove 422 and a second sliding groove 424 respectively corresponding to the two first guiding components 122 therein. The first sliding groove 422 is a long and narrow aperture defined proximate to the end board 44, and an end of the first sliding groove 422 proximate to the end board 44 enlarges to form a first assembling hole 4222. The first guiding component 1222 proximate to the electronic connector 126 can be inserted into the first assembling hole 4222 and slide along the first sliding groove 422. An assembling hook 425 bending towards the end board 44 is formed on an outer side of the side board 42 and positioned between the first assembling hole 4222 and the end board 44. The second sliding groove 424 is a long and narrow aperture positioned to be collinear with the first sliding groove 422. An end of the second sliding groove 424 proximate to the first sliding groove 422 enlarges to form a second assembling hole 4242, wherein the width of the second assembling hole 4242 is equal to the width of the first assembling hole 4222, and the length of the second assembling hole 4242 is longer than the length of the first assembling hole 4222. The first guiding component 1222 proximate to the end wall 162 can be inserted into the first assembling hole 4242 and slide along the first sliding groove 424. A limiting protrusion 426 bending towards the side board 43 is formed on an inner side of the side board 42 and positioned between the second assembling hole 4242 and the first sliding groove 422.

The side board 43 defines a third sliding groove 432 corresponding to the second guiding component 1242 and a fourth sliding groove 434 corresponding to the third guiding component 1252. The third sliding groove 432 is positioned opposite to the second sliding groove 424. The shape of the third sliding groove 432 is similar to that of the first sliding groove 422, and an end of the third sliding groove 432 proximate to the end board 44 enlarges to form a third assembling hole 4322. The second guiding component 1242 can be inserted into the third assembling hole 4322 and slide along the third sliding groove 432. The fourth sliding groove 434 extends to an end of the end board 44. The end board 44 defines a fourth assembling hole 441 communicating with the fourth sliding groove 434 and corresponding to the third guiding component 1252. The third guiding component 1252 can be inserted into the fourth assembling hole 441 and slide along the fourth sliding groove 434. The end board 44 also defines a connecting hole 442 in a middle portion thereof to enable the accessory 30 being electronically connected to the electric connector 126.

The positioning member 50 includes an approximately prism-shaped main body 52 and two coiled cylindrical springs 53. The main body 52 includes two cylindrical assembling poles 522 corresponding to the coiled springs 53 protruding from one surface thereon, and a wedge-shaped holding component 524 protruding from one end of another surface of the main body 52 opposite to the assembling poles 522. Two ends of the main body 52 extends against each other to form two retaining sides 526 respectively corresponding to the two limiting sides 1238. An end of the main body 52 opposite to the holding component 524 defines a wedged contact portion 528 corresponding to the limiting protrusion 426. The springs 53 can be respectively coiled on the assembling poles 522.

The elastic member 60 is a coiled cylindrical spring and includes two fixing rings 62 respectively formed on two ends thereof. The two fixing rings 62 can be respectively coiled on the connecting hook 127 and the assembling hook 425 to be fixed thereon.

The cover 20 includes a panel 201 corresponding to the base board 12 and a frame 202 perpendicularly connected to the whole side of the panel 201. The frame 202 corresponds to the side walls 141, 142 and the end walls 161, 162 and defines a gap 22 corresponding to the opening 163. The accessory 30 corresponds to the gap 22 and the opening 163, for example, a battery or a memory card. The accessory 30 defines a holding hole 32 corresponding to the holding component 524 in an outer surface thereof.

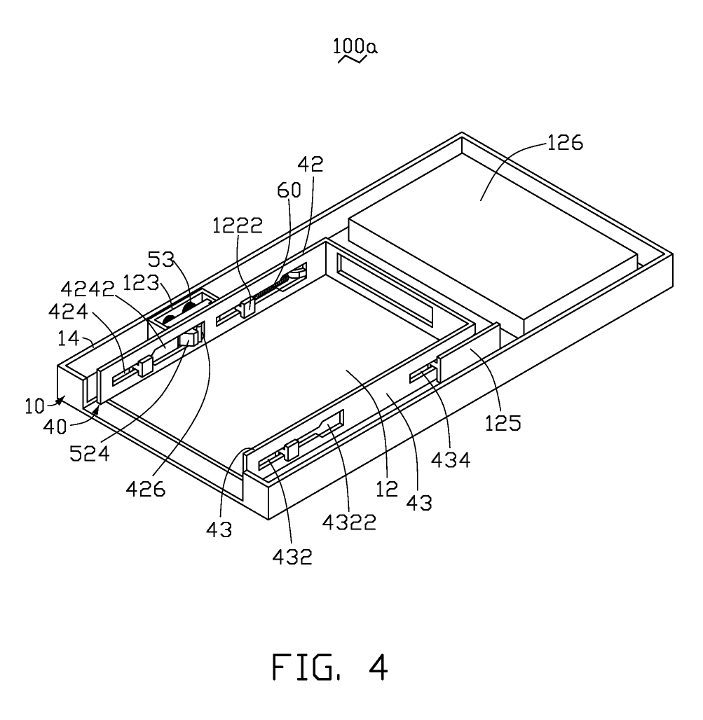

Also referring to FIG. 4, in assembly, the two springs 53 are coiled on the assembling poles 522, correspondingly. The positioning member 50 is then received in the receiving space 1234. The retaining sides 526 are correspondingly limited by the limiting sides 1238. The springs 53 are positioned between the main body 52 and the connecting wall 123. Each spring 53 has one end pressed on an inner side of the connecting wall 123 and another end pressed on the main body 52.

The sliding member 40 is then assembled to the housing 10. In particular, the sliding member 40 is pushed towards the end board 44 of the side wall 141, such that the first guiding component 1222 proximate to the electronic connector 126 are inserted into the first assembling hole 4222, the first guiding component 1222 proximate to the end wall 162 is inserted into the first assembling hole 4242, the second guiding component 1242 is inserted into the third assembling hole 4322, the third guiding component 1252 is aligned with the fourth assembling hole 441, and the holding component 524 is pressed towards the connecting wall 322 by the side board 42. The sliding member 40 is then pushed towards the electronic connector 126, thus the two first guiding components 1222 are respectively slid along the first sliding groove 422 and the second sliding groove 424, the second guiding component 1242 is slid along the third sliding groove 432, and the fourth guiding component 1252 is slid along the fourth sliding groove 434. With sliding of the sliding member 40, the holding component 524 is moved to be aligned with the first assembling hole 4242. Thus, the holding component 524 is pushed to be inserted in the first assembling hole 4242 by the resiling springs 53 to engage with the sliding member 40, and the sliding member 40 is stopped when the limiting protrusion 426 is blocked by the holding component 524 extending between the side boards 42 and 43 from the first assembling hole 4242. In this way, the sliding member 40 is slidably assembled on the housing 10 and positioned perpendicularly to the main board 12.

The two fixing rings 62 of the elastic member 60 are respectively coiled on the connecting hook 127 and the assembling hook 425 to be fixed thereon. When the sliding member 40 is pushed towards the electronic connector 126, the elastic member 60 is extended. Finally, the cover 20 is assembled on the housing 12 to cover the sliding member 40, the positioning member 50 and the elastic member 60. The gap 22 cooperates with the opening 163 to form a receiving aperture 70.

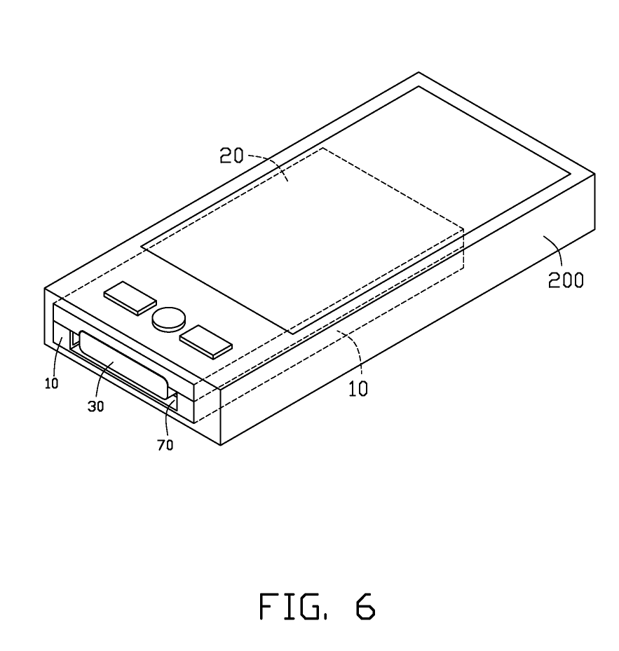

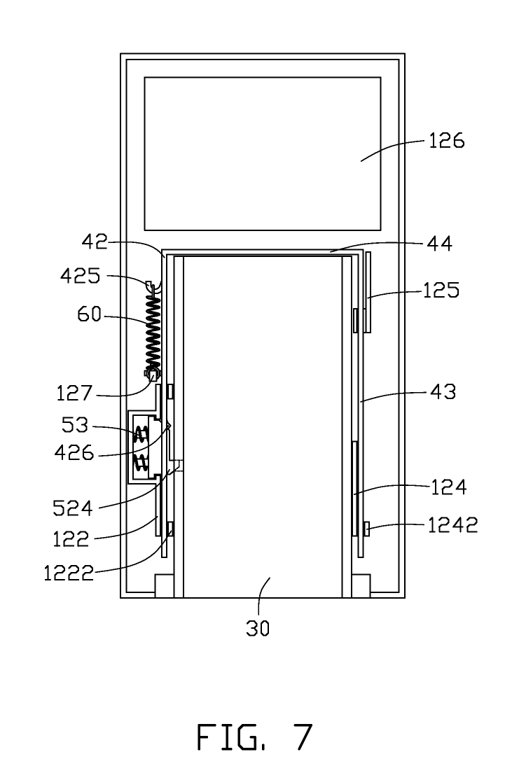

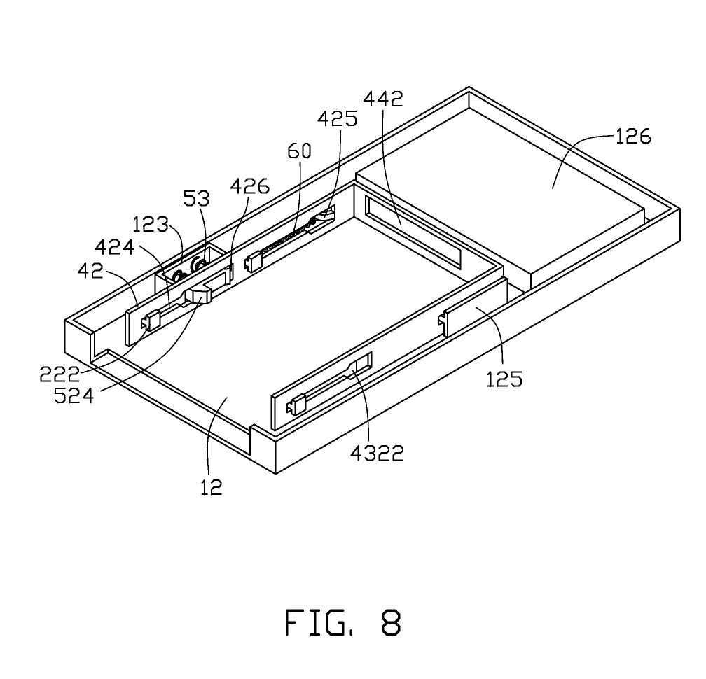

Also referring to FIG. 6, in use, the accessory 30 is inserted into the receiving aperture 70 and pushed towards the end board 44 of the sliding member 40 to approach the end wall 161, with the holding hole 32 positioned towards the side wall 141. Thus, the accessory 30 is received in the sliding member 40 and drives the sliding member 40 to move inwards. The wedged holding component 524 can facilitate the accessory 30 to be inserted in the receiving aperture 70. Also referring to FIG. 7 and FIG. 8, the accessory 30 is pushed to approach the electronic connector 126 to be electronically connected to the electronic connector 126 through the connecting hole 442. The elastic member 60 is elongated by the assembling hook 425 moving towards the electronic connector 126 with the sliding member 40. When the accessory 30 is in contact with the electronic connector 126, the holding hole 32 is moved to be aligned with the holding component 524. Thus, the holding component 524 is pushed by the resiling springs 53 to engage with the holding hole 32, such that the accessory 30 is held in the accessory holding mechanism 100 and electronically connected thereto. The electronic connector 126 can be connected to other circuits of a portable electronic device, thus the accessory 30 can be used. An end of the accessory 30 is exposed out from the receiving aperture 70 to facilitate the disassembly operation.

When the held accessory 30 needs to be removed from the accessory holding mechanism 100, an end of the accessory 30 exposing out from the receiving aperture 70 is pressed inwards. The accessory 30 is pushed towards the sliding member 40 to further approach the end wall 161, thereby the sliding member 40 being driven to move towards the end wall 161, and the elastic member 60 being further elongated. When the pressure on the accessory 30 is removed, the elastic member 60 rebounds to pull the sliding member 40 and the accessory 30 away from the electronic connector 126 and towards the end wall 162. When the limiting protrusion 426 is driven to contact the contact portion 528, it pushes the contact portion 528 due to the inertia of the moving sliding member 40 and the accessory 30, such that the main body 52 is pushed towards the side wall 141 to enter the receiving space 1234, and the holding component 524 is driven to exit from the holding hole 32 and release the accessory 30 and the sliding member 40. Therefore, the positioning member 50 moves in a direction perpendicular to the direction of the movement of the sliding member 40 and the accessory 30 away from the accessory 30, and does not interfere with the movement of the sliding member 40 and the accessory 30. The sliding member 40 keeps moving away from the electronic connector 126 until the elastic member 60 rebounds to its initial shape. Thus, the sliding member 40 and the accessory 30 are driven to partially expose out from the receiving aperture 70, such that the accessory 30 is driven to exit from the accessory holding mechanism 100 and can be removed from the accessory holding mechanism 100.

Understandably, in the accessory holding mechanism 100, either of the two springs 53 can be omitted. Correspondingly, either of the two assembling poles 522 can also be omitted.

The accessory holding mechanism 100 can easily hold the accessory 30 and electronically connect thereto, and the accessory 30 can be pushed inwards to be driven to exit from the accessory holding mechanism 100. Furthermore, the accessory holding mechanism 100 need not any cam mechanisms. Compared with many conventional holding mechanisms, the accessory holding mechanism 100 has a simpler structure and spends less cost.

It is to be further understood that even though numerous characteristics and advantages of the present embodiments have been set forth in the foregoing description, together with details of structures and functions of various embodiments, the disclosure is illustrative only, and changes may be made in detail, especially in matters of shape, size, and arrangement of parts within the principles of the present invention to the full extent indicated by the broad general meaning of the terms in which the appended claims are expressed.

What is claimed is:

1. An accessory holding mechanism used in a portable electronic device for holding an accessory therein, comprising:
a housing;
a sliding member slidably assembled on the housing and receiving the accessory therein;
a positioning member movably mounted on the housing; and
an elastic member mounted between the housing and the sliding member; wherein the positioning member engages with the sliding member and the accessory to hold the accessory and the elastic member is elongated when the accessory is pushed into the sliding member, and the elastic member rebounds to drive the positioning member to release the accessory and drive the accessory to exit from the accessory holding mechanism through the sliding member after the held accessory is further pushed into the sliding member.

2. The accessory holding mechanism as claimed in claim 1, further comprising a cover corresponding to the housing, the cover being assembled on the housing to cover the sliding member, the positioning member and the elastic member and to cooperate with the housing to form a receiving aperture for the accessory being inserted in or exiting from the holding accessory mechanism.

3. The accessory holding mechanism as claimed in claim 1, wherein the housing includes a plurality of protruding guiding components formed thereon and the sliding member defines a plurality of sliding grooves corresponding to the guiding components, and the guiding components are correspondingly slidably received in the sliding grooves to slidably assemble the sliding member on the housing.

4. The accessory holding mechanism as claimed in claim 3, wherein each sliding groove includes an enlarged assembling hole formed on one end thereof for a corresponding guiding component being inserted therein and then slidably received in the sliding groove.

5. The accessory holding mechanism as claimed in claim 4, wherein the positioning member includes a main body and two springs mounted between the main body and the housing to drive the main body to move, the main body including a holding component for inserting an assembling hole to engage with the sliding member and engaging with the accessory received in the sliding member and a contact portion for being pressed by the sliding member to release the accessory.

6. The accessory holding mechanism as claimed in claim 5, wherein both the holding component and the contacting portion are wedge-shaped, and the sliding member includes a limiting protrusion corresponding to the contacting portion formed thereon for pushing the contacting portion to release the accessory when the sliding member is driven by the resiling elastic member.

7. The accessory holding mechanism as claimed in claim 1, wherein the housing defines a receiving space for receiving the positioning member therein.

8. The accessory holding mechanism as claimed in claim 1, wherein the movement direction of the positioning member is perpendicular to the movement direction of the sliding member and the accessory.

9. An accessory holding mechanism used in a portable electronic device for holding an accessory therein, comprising:
a housing;
a sliding member slidably assembled on the housing and receiving the accessory therein;
a positioning member movably mounted on the housing for engaging with the sliding member and the accessory to held the accessory; and
an elastic member mounted between the housing and the sliding member; wherein the elastic member is elongated when the held accessory and the sliding member are pushed into the housing; when the pressure on the held accessory is removed, the elastic member rebounds to drive the sliding member and the accessory to exit from the housing, and the positioning member is driven to release the accessory due to the inertia of the moving sliding member and the accessory.

10. The accessory holding mechanism as claimed in claim 9, further comprising a cover corresponding to the housing, the cover being assembled on the housing to cover the sliding member, the positioning member and the elastic member and to cooperate with the housing to form a receiving aperture for the accessory being inserted in or exiting from the holding accessory mechanism.

11. The accessory holding mechanism as claimed in claim 9, wherein the housing includes a plurality of protruding guiding components formed thereon and the sliding member defines a plurality of sliding grooves corresponding to the guiding components, and the guiding components are correspondingly slidably received in the sliding grooves to slidably assemble the sliding member on the housing.

12. The accessory holding mechanism as claimed in claim 11, wherein each sliding groove includes an enlarged assembling hole formed on one end thereof for a corresponding guiding component being inserted therein and then slidably received in the sliding groove.

13. The accessory holding mechanism as claimed in claim 12, wherein the positioning member includes a main body and two springs mounted between the main body and the housing to drive the main body to move, the main body including a holding component for inserting an assembling hole to engage with the sliding member and engaging with the accessory received in the sliding member and a contact portion for being pressed by the sliding member to release the accessory.

14. The accessory holding mechanism as claimed in claim 13, wherein both the holding component and the contacting portion are wedge-shaped, and the sliding member includes a limiting protrusion corresponding to the contacting portion formed thereon for pushing the contacting portion to release the accessory when the sliding member is driven by the resiling elastic member.

15. The accessory holding mechanism as claimed in claim 9 wherein the housing defines a receiving space for receiving the positioning member therein.

16. The accessory holding mechanism as claimed in claim 9, wherein the movement direction of the positioning member is perpendicular to the movement direction of the sliding member and the accessory.
